(19) United States
(12) Patent Application Publication
(10) Pub. No.: US 2026/0059665 A1
(43) Pub. Date: Feb. 26, 2026

(54) COMPRESSION DEFINED BROACHING MOUNTS FOR A COMPRESSION-ATTACHED MEMORY MODULE (CAMM) CONNECTOR PLATFORM

(71) Applicants: XILINX, INC., San Jose, CA (US); Advanced Micro Devices, Inc., Santa Clara, CA (US)

(72) Inventors: Hing Yan TO, Cupertino, CA (US); Christopher Edward COX, Folsom, CA (US)

(21) Appl. No.: 18/815,686

(22) Filed: Aug. 26, 2024

(51) Int. Cl. H05K 1/14

(52) U.S. Cl. CPC H05K 1/144; H05K 2201/041; H05K 2201/10159; H05K 2201/1025; H05K 2201/10378; H05K 2201/2072

(57) ABSTRACT

A compression-defined broaching mount for compression-attached memory module (CAMM) includes a plurality of pins configured to retain a plurality of circuit boards in a compressed position. The pins may include a snap-pin, a push-pin, and/or a spring-loaded pin. The pin is removable. The CAMM may include a flat washer and/or a counter-sunk washer configured to receive the pin. The counter-sunk washer may have an opening to a chamber therein, where an inner surface of the chamber has a channel to receive a locking member of the pin. The CAMM may include a compressible material to exert a force when the pin is in a locked position. The compressible material may include an O-ring, a gasket, and/or a film. The CAMM may include a visual compression indicator.

### TECHNICAL FIELD

Examples of the present disclosure generally relate to compression-defined broaching mounts for a compression-attached memory module (CAMM) connector platform.

### BACKGROUND

A compression-attached memory module (CAMM) compresses a memory module, an interposer (i.e., an interconnector), and a printed circuit board (PCB), together such that electrical pads of the memory module and the PCB contact respective electrical pads of the interposer (i.e., solderless electrical connections).

Advantages of CAMMs include reduced thicknesses, replaceable modules, faster speeds, higher capacities, and higher memory bandwidth. A disadvantage of CAMMs is that they are mounted with screws, which requires tools and proper torque. Insufficient torque may result in open contacts. Too much torque may result in bending/warping of the memory module and/or the PCB, which may result in open contacts and/or damage to the memory module, the interposer, and/or the PCB.

CAMMs are addressed in JESD318, Compression Attached Memory Module (CAMM2) Common Standard (Ver. 1.02 November 2023).

### SUMMARY

Techniques for compression-defined broaching mounts for a compression-attached memory module (CAMM) connector platform are described. One example is an apparatus that includes a pin having an elongated body that inserts into aligned openings of a plurality of circuit boards, and a locking member that retains the pin in a locked position in which the circuit boards are pressed against one another under a compression force.

Another example described herein is an apparatus that includes a plurality of circuit boards, including an interposer circuit board that provides electrical connections between electrical contacts of adjacent ones of the circuit boards. The apparatus further includes a plurality of pins having elongated bodies that insert into respective aligned openings of the circuit boards, and a locking member that retains the pins in a locked position in which the circuit boards are pressed against one another under a compression force.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 depicts a snap-pin, according to an embodiment.

FIG. 2 depicts a compression-attached circuit assembly, according to an embodiment.

FIG. 3 depicts a length of the snap-pin of FIG. 1, according to an embodiment.

FIG. 4 depicts a compression-attached circuit assembly that includes washers, according to an embodiment

FIG. 5 depicts a compression-attached circuit assembly that includes a counter-sunk washer, according to an embodiment.

FIGS. 6A through 6D illustrate the counter-sunk washer from respective view-points, according to an embodiment.

FIG. 7 depicts a counter-sunk washer having an internal channel, according to an embodiment.

FIG. 8 depicts a push-pin, according to an embodiment.

FIGS. 9A and 9B depict a counter-sunk washer having multiple internal channels, according to an embodiment.

FIG. 10 depicts a compression-attached circuit assembly that includes gaskets or O-rings, according to an embodiment.

FIG. 11 depicts a compression-attached circuit assembly having a counter-sunk washer and gaskets or O-rings, according to an embodiment.

FIG. 12 depicts a surface having a deformable material thereon, and associated visual compression indicators, according to an embodiment.

FIG. 13 depicts a spring-loaded pin, according to an embodiment.

FIG. 14 depicts a compression-attached circuit assembly, according to an embodiment.

FIG. 15 depicts an integrated circuit device that includes compression-attached circuit assembly, according to an embodiment.

FIG. 16 depicts effects of bending/warping on electrical connections amongst layers of a compression-attached circuit assembly.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe compression-defined broaching mounts for a compression-attached memory module (CAMM) connector platform.

A CAMM may include a bottom bolster plate having threaded openings to receive mounting screws to avoid warpage of the PCB. The amount of torque to be applied to the screws depends on the thickness of the host system board, which can vary in term of thickness and rigidity. Over torqueing the screws can damage the compression CAMM and/or the PCB. Under torqueing the screws can lead to poor electrical contact. The torque of the screws, the thickness of the bottom bolster plate, and the rigidity of the PCB thus need to be accurately designed. It is also time consuming to assemble CAMMs with screws in a high volume manufacturing environment.

Compression-defined broaching mounts, as disclosed herein, include insertable pins, which do not require torque and thus reduce potential damage to the CAMM and PCB.

Compression-defined broaching mounts provide accurate, definable, evenly-distributed compression to ensure appropriate electrical connections/conductivity.

Compression-defined broaching mounts improve high volume assembly manufacturing reliability.

Compression-defined broaching mounts, as disclosed herein, may include one or more of a variety of compression-inducing features and visual compression indicators.

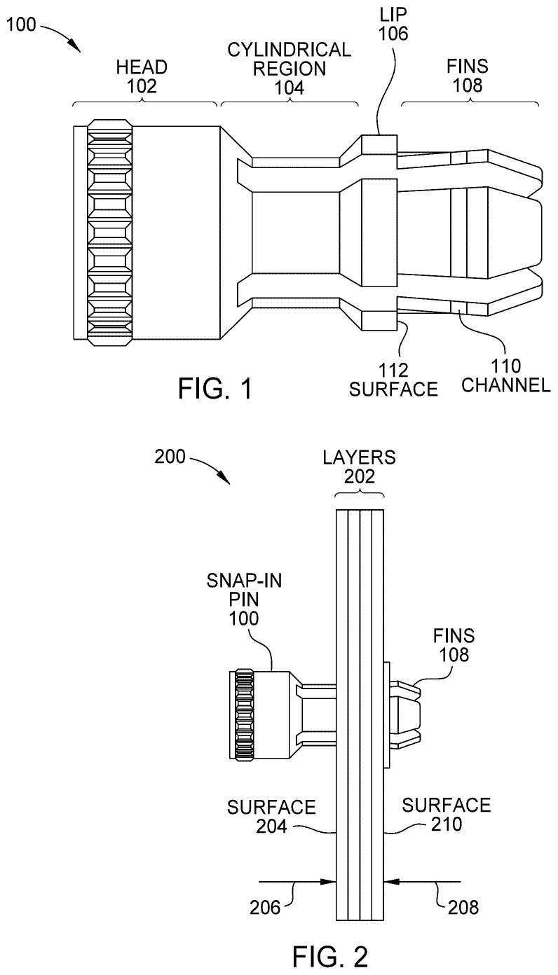

FIG. 1 depicts a snap-pin 100, according to an embodiment. In the example of FIG. 1, snap-pin 100 includes a head 102, a cylindrical region 104 extending from the head, a flange or lip 106 extending outwardly from cylindrical region 104, at a distal end of cylindrical region 104, and deformable fins 108 extending from the end of cylindrical region 104.

Other examples of retaining pin 100 are provided further below.

FIG. 2 depicts a compression-attached circuit assembly (assembly) 200, according to an embodiment. Assembly includes snap-pin 100 and layers 202. Layers 200 may include layers of an integrated circuit device. Assembly may represent, for example and without limitation, a compression-attached memory module (CAMM).

In FIG. 2, snap-pin 100 is inserted through openings of sheets 110 by compressing fins 108 inwardly such that a radius of fins 108 is less than a radius of the openings. When fins 108 emerge from layers 102, as depicted in FIG. 2, fins 108 are released and expand outwardly to lock snap-pin 100 in place. In an example, fins 108 are compressed manually. In another example, fins 108 are initially held in a compressed position by a flexible ring (e.g., a gasket/O-ring) positioned within channels 110 of fins 108. As snap-pin 100 is inserted through the openings of layers 202, friction forces the ring out of channel 110 and along cylindrical region 104 towards head 102. Thereafter, the ring may become wedged between a surface 112 of lip 106 and a surface 204 of layers 102, and may serve as a compression device to apply compression layers 202 against one another as depicted by arrows 206 and 208. Snap-pin 110 may be removed from layers 202 my compressing fins 108 inwardly, and pulling snap-pin 100 away from layers 202.

Compression-attached circuit assembly (assembly) 200 is not limited to snap-pins. Alternative retaining pins are disclosed further below.

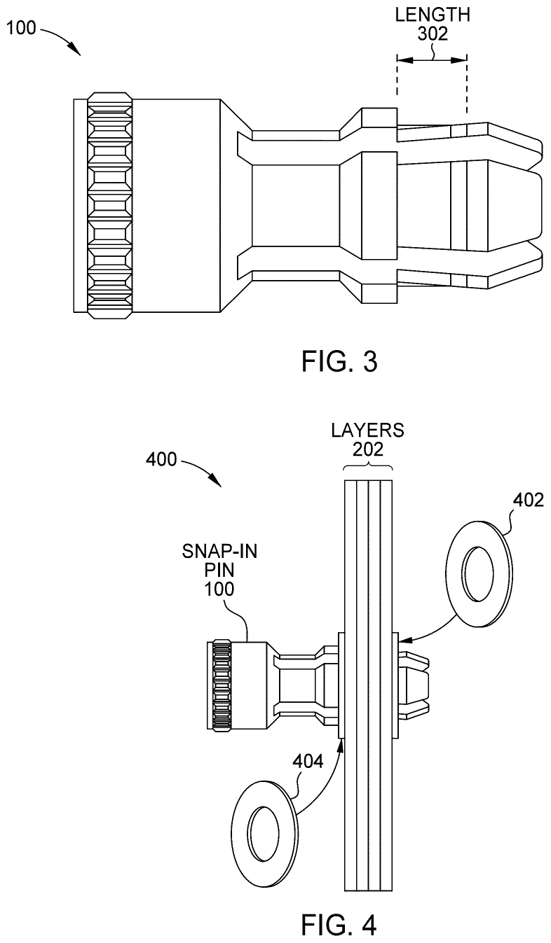

FIG. 3 depicts a length 302 of snap-pin 100, according to an embodiment. Snap-pin 100 may be designed/manufactured with a desired length 302, which may be based on an intended application (e.g., based on a width of layers 202 and a desired compression force). Snap-pin 100 may be designed with a length 302 that is determined based on computer-simulations. The computer simulation may account for changes/variations due do manufacturing processes, materials, environmental conditions (e.g., temperature, humidity, pressure, and/or vibrations), and/or time/age.

FIG. 4 depicts a compression-attached circuit assembly (assembly) 400, according to an embodiment. Assembly 400 includes snap-pin 100, layers 202, and flat washers 402 and 404.

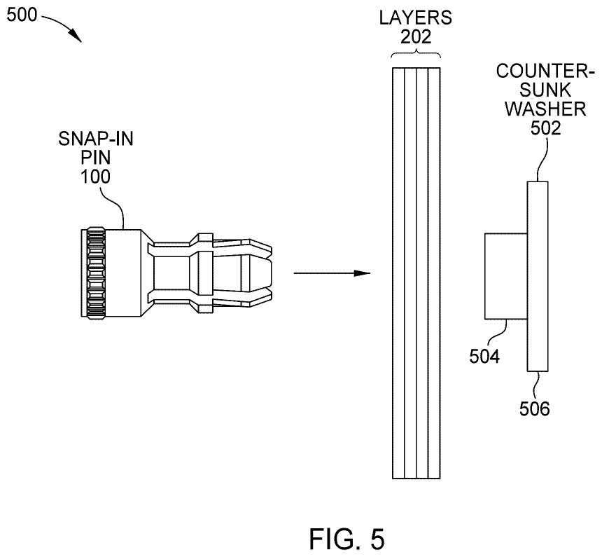

FIG. 5 depicts a compression-attached circuit assembly (assembly) 500, according to an embodiment. Assembly 500 includes snap-pin 100, layers 202, and a counter-sunk washer (washer) 502. A counter-sunk portion 504 of washer 502 has an opening that extends a length of counter-sunk portion 504. An outer radius of a counter-sunk portion 504 of washer may be less than a radius of the openings of layers 202, such that counter-sunk portion 504 may be inserted into the openings of layers 202. An inner radius of counter-sunk portion 504 may be less than a compressed radius of fins 108, such that fins 108, when compressed, slide into the opening of counter-sunk portion 504.

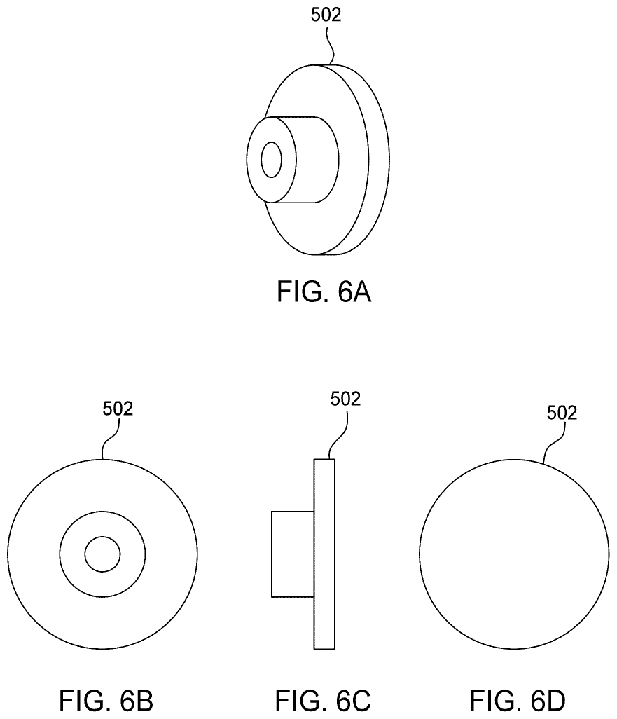

In an example, the opening through counter-sunk portion 504 extends through a base 506 of washer 502, such that fins 108 expand when fins emerge from the opening through base 506. In another example, base 506 is solid, such as depicted in FIGS. 6A through 6D.

FIGS. 6A through 6D illustrate counter-sunk washer 502 from respective view-points, according to an embodiment.

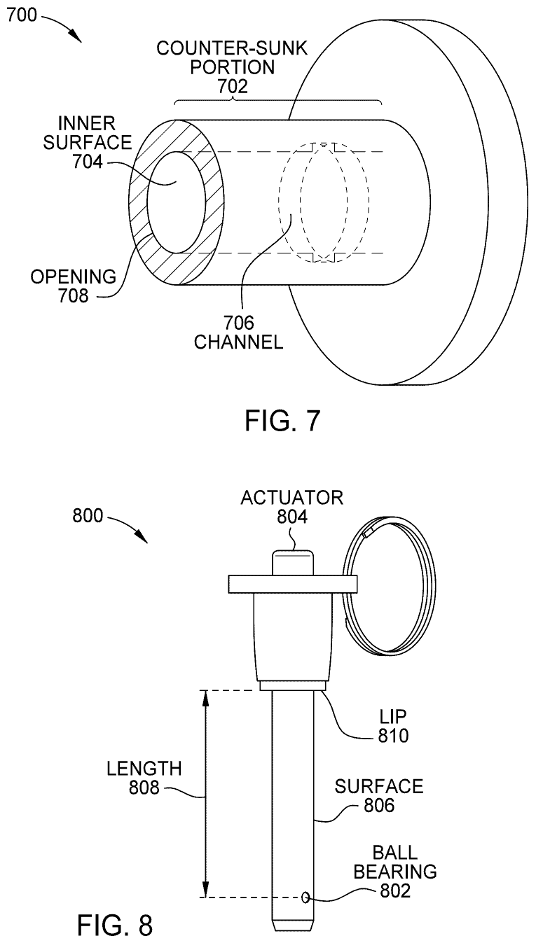

FIG. 7 depicts a counter-sunk washer (washer) 700, according to an embodiment. Washer 700 includes a counter-sunk portion 702 having an inner surface 704. Inner surface 704 has a channel 706. In this example, snap-pin 100 is inserted into an opening 708, with fins 108 compressed inwardly. When fins 108 reach channel 706, fins 108 expand outwardly into channel 706 to secure snap-pin 100 and washer 700 to one another.

FIG. 8 depicts a push-pin 800 that can be used in place of snap-pin 100, according to an embodiment. Push-pin 800 includes a spring-loaded retractable ball bearing 802 and an actuator 804. When actuator 804 is in a resting position, ball bearing 802 extends outwardly from an opening in a surface 806 due to pressure applied by an internal spring. When actuator 804 is pressed, the internal spring is released or retracted, such that ball bearing 802 is not forced to extend from the opening.

In the example of FIG. 7, snap-in pin 100 may be replaced with push-pin 800 such that, when actuator 804 is pressed, push-pin can be inserted through the openings of layers 202. When the region of push-pin 800 in which ball bearing 802 resides, emerges from the openings of layers 200, and when actuator 804 is released, ball bearing 802 extends outwardly from the opening in surface 806 to lock push-pin 100 in place. Push-pin 800 may be designed/manufactured such that a length 808 of push-pin 800, between a flange or lip 808 and ball bearing 802, ensures that a desired compression force is applied in the direction of arrows 206 and 208.

In the example of FIG. 8, snap-in pin 100 may be replaced with push-pin 800 such that, when actuator 804 is pressed, push-pin can be inserted into opening 708 of washer 700. When the region of push-pin 800 in which ball bearing 802 resides, reaches channel 706, and when actuator 804 is released, ball bearing 802 extends outwardly from the opening in surface 806 into channel 706 to lock push-pin 100 in place. Push-pin 800 may be designed/manufactured such that length 808 of push-pin 800 ensures that a desired compression force is applied.

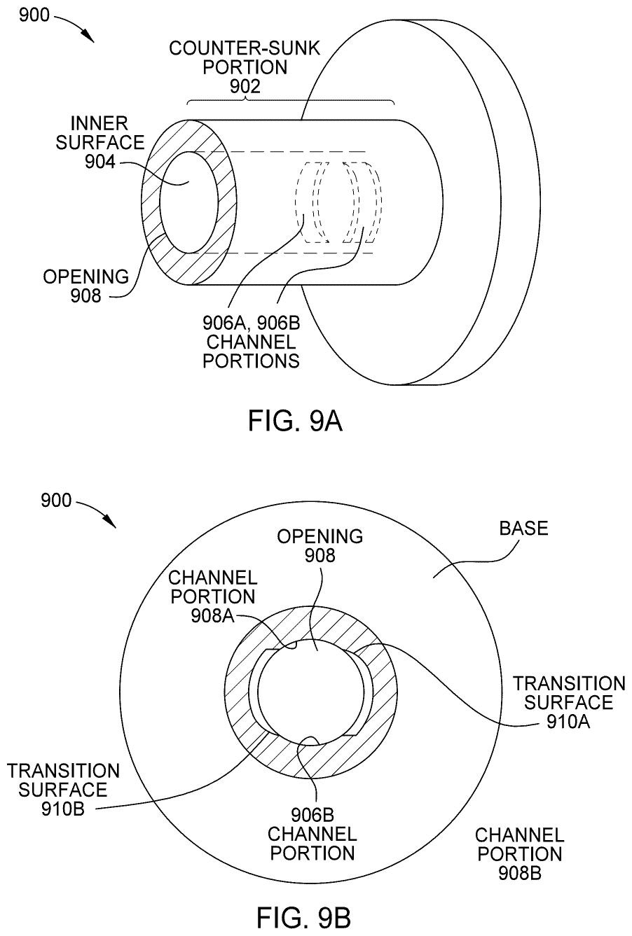

FIG. 9 depicts a counter-sunk washer (washer) 900, according to an embodiment. Washer 900 includes a counter-sunk portion 902 having an inner surface 904. Inner surface 904 has channel portions 906A and 906B, channel portions 906A and 906B have respective transition surfaces 910-A and 910-B, and snap-pin 100 has corresponding first and second fins. In this example, snap-pin 100 is inserted into an opening 908, with the first and second fins compressed inwardly. When the first and second fins reach respective channel portions 906A and 906B, the first and second fins expand outwardly into channel portions 906A and 906B to secure snap-pin 100 and washer 900 to one another. Snap-pin 100 may be removed by twisting head 110 such that transition surfaces 910-A and 910-B compress the first and second fins to permit removal of snap-pin 100.

A compression-attached circuit assembly, as disclosed herein, may include one or more features that apply compression in the directions of arrows 206 and 208, provide visual indications of compression forces (i.e., compression indicators), and/or absorbs vibration. An example is provided above with respect to a ring within channel 110 of snap-pin 100. Additional examples are provided below. The examples below include mechanical features, such as gaskets, O-rings, and surface coatings made of a relatively firm deformable/compressible material(s). The mechanical features are compressed when pins are inserted in locked positions such that the mechanical features provide a desired compression force. The examples below include further mechanical features, such as relatively soft deformable material/padding to absorb vibration. The examples below include further mechanical and electro-chemical features that provide visual indications of compressive force applied to a compression-attached circuit assembly. The visual indicator(s) may indicate whether a minimum desired compression and/or a maximum permissible compression is applied.

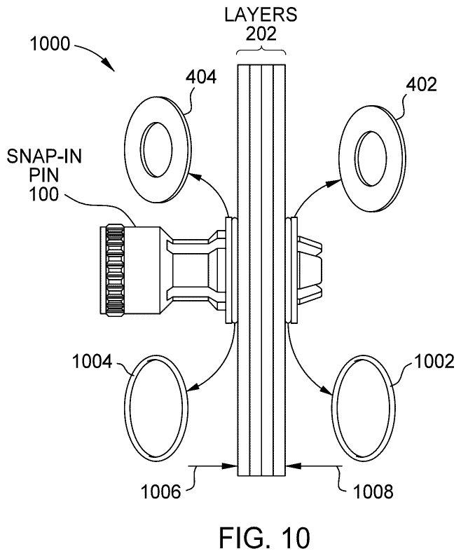

FIG. 10 depicts a compression-attached circuit assembly (assembly) 1000, according to an embodiment. Assembly 1000 includes snap-pin 100, layers 202, flat washers 402 and 404, and gaskets or O-rings 1002 and 1004. In an example, O-rings 1002 and 1004, and length 302 (FIG. 3), are designed/manufactured/selected such that, when snap-in 100 (or push-pin 800) is in a locked position, O-rings 1002 and 1004 are compressed such that O-rings 1002 and 1004 apply a desired compression force in the direction of arrows 1006 and 1008. In a further example, an extent or degree of compression of O-rings 1002 and 1004, serves as visual confirmation that the desired compression force is applied. The extent or degree of compression may be determined based on a shape of O-rings 1002 and 1004, based on radii of O-rings 1002 and 1004 relative to radii of washers 404 and 402, and/or based on radii of O-rings 1002 and 1004 relative to markings on nearby surfaces. O-rings 1002 and 1004 (or gaskets), may be made of a relatively firm deformable material. The firmness may be selected based on a desired compression force. In another example, one of O-rings 1002 and 1004 is omitted. In another example, flat washer 402 may be replaced with a counter-sunk washer, such as described in one or more examples herein.

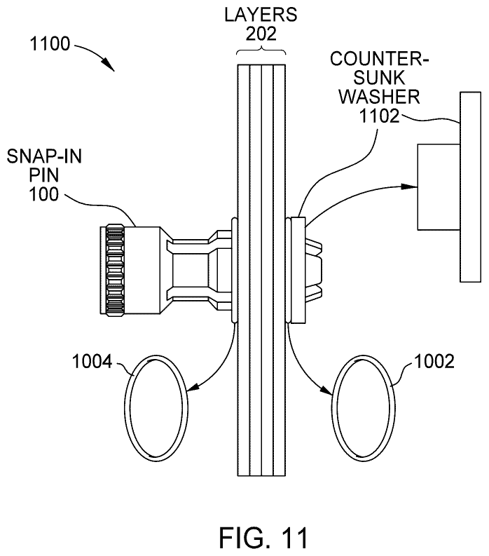

FIG. 11 depicts a compression-attached circuit assembly (assembly) 1100, according to an embodiment. Assembly 1100 includes snap-pin 100, layers 202, a counter-sunk washer 1102, and O-rings 1002 and 1004. Counter-sunk washer 1102 may be similar to counter-sunk washer 502, 700, or 900. Snap-pin 100 may be replaced with push-pin 800.

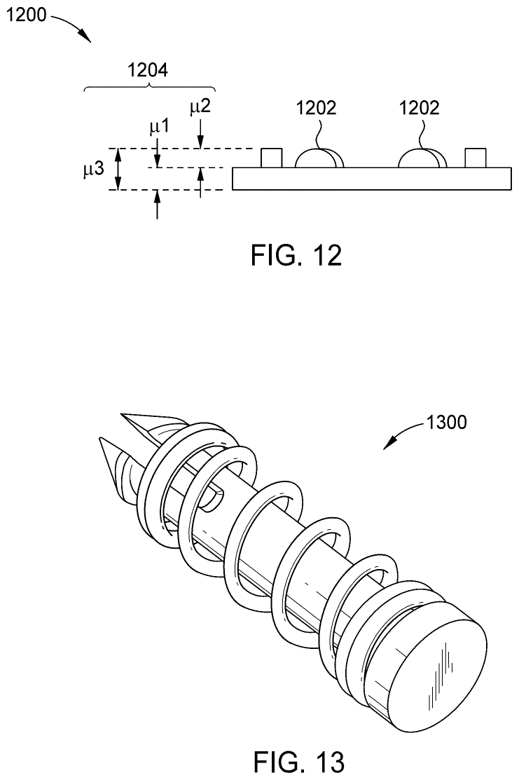

In another example, surface 112 (FIG. 1), surface 204 (FIG. 1) and/or a surface that faces surface 204 (e.g., surface 112 in FIG. 1 or a surface of washer 404 in FIG. 4), may include a feature and/or a substance/coating to impart compression (e.g., a compressible material such as rubber) and/or a to indicate a compression force. Alternatively, or additionally, a surface 210 of an outer-most one of layers 202, or a surface that faces surface 210 may include may include a feature and/or a substance/coating a substance to impart compression and/or to indicate a compression force. FIG. 12 depicts a surface 1200 having a deformable material 1202 thereon, and visual compression indicators 1204, according to an embodiment. In another example, a surface includes a thin film of an electro-chemical material (e.g., a piezo-chromic electric material), that reflects light (electro-magnetic radiation), having a frequency that corresponds to a compression force applied to the material.

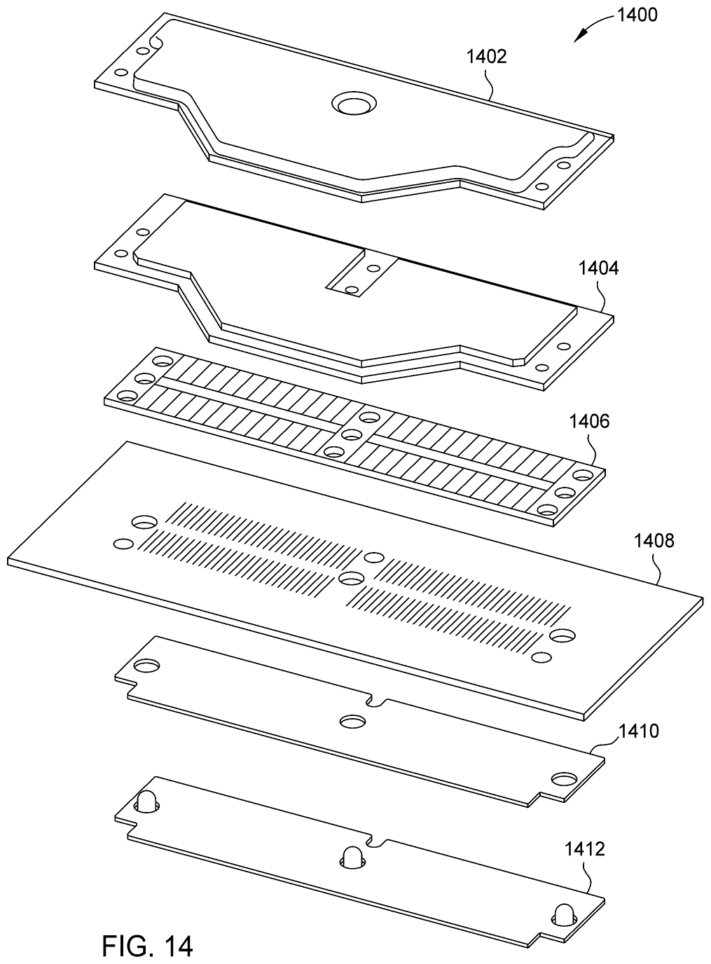

FIG. 13 depicts a spring-loaded pin 1300, according to an embodiment. Spring-loaded pin 1300 may be used in place of snap-pin 100 or push-pin 800 in one or more examples herein. Spring-loaded pin 1300 may be designed such that the spring applies a desired compression force. Alternatively, or additionally, spring-loaded pin 1300 may be adjustable for a desired compression force.

FIG. 14 depicts a compression-attached circuit assembly (assembly) 1400, according to an embodiment. Assembly 1400 includes layers 1402 through 1412. Layer 1402 may include an electro-magnetic interference (EMI) shield. Layer 1404 includes an integrated circuit device (e.g., memory) having electrically conductive pads on an underside surface that faces layer 1406. Layer 1406 includes electrically conductive pads on first and second opposing surfaces, and internal electrically conductive connections between the electrically conductive pads of the first and second surfaces. Layer 1408 includes a circuit board (e.g., a mother board), having electrically conductive pads on a surface that faces layer 1406. Layer 1410 includes a non-electrically conductive material (i.e., an insulator). Layer 1408 is a substantially rigid, non-deformable plate (e.g., a metal plate).

Layer 1402 has openings 1420, 1422, and 1424 to receive a pin (e.g., snap-pin 100 or push-pin 800). Layers 1404 through 1412 have corresponding openings. When a pin is inserted through the openings and secured as disclosed in one or more examples herein, compression forces are applied to compress layers 1402 through 1412 towards one another, such that the electrically conductive pads of layers 1404 and 1408 contact respective electrically conductive pads of layer 1406.

In other examples, layer 1402, layer 1410, and/or layer 1412 may be omitted. For example, layer 1402 may be omitted where EMI is not of concern.

As another example, layer 1408 may be considered useful to limit/reduce bending/warping (e.g., FIG. 16) of other layers of assembly 1400, if assembly 1400 were secured with screws (i.e., compression forces applied by screws depends on torque applied when driving the screws). Insulating layer 1410 may be useful to prevent layer 1412 from shorting electrically conductive pads on an underside surface of layer 1408. Bending/warping may be of less concern, or of no concern, when assembly 1400 is secured with pins disclosed herein. Layers 1410 and 1412 may thus be omitted, which may reduce weight and manufacturing costs. Alternatively, layer 1408 may be retained in place of flat washers 402.

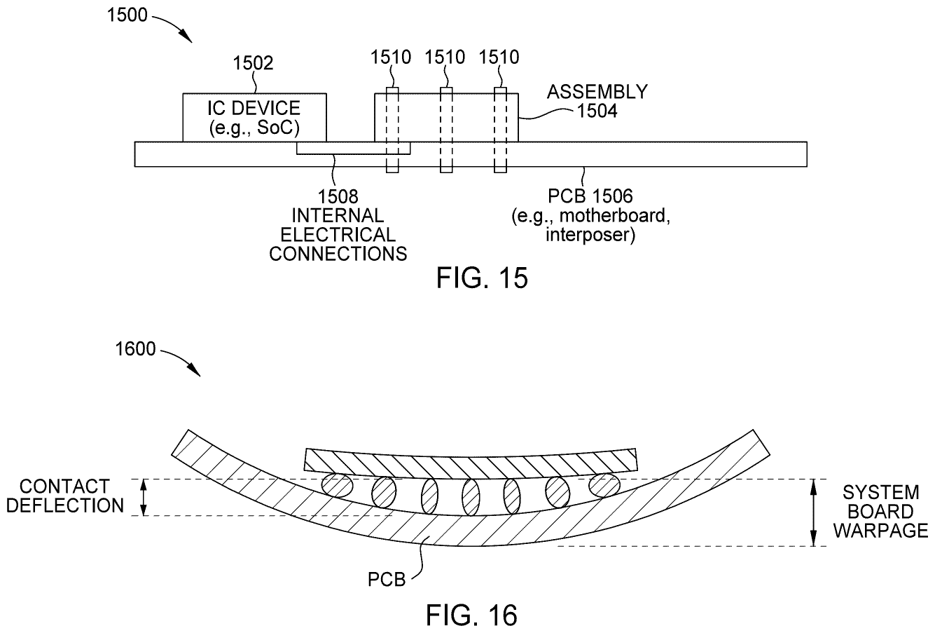

FIG. 15 depicts an integrated circuit device (device) 1500 that includes compression-attached circuit assembly (assembly), according to an embodiment. Device 1500 includes an integrated circuit device 1502, a compression-attached circuit assembly (assembly) 1504, and a printed circuit board (PCB) 1506 that includes internal electrical connections 1508 to permit integrated circuit device 1502 and assembly 1504 to communicate with one another. In an example, integrated circuit device 1502 includes a system-on-chip (SoC), assembly 1504 includes a CAMM, and PCB 1506 includes a motherboard or other interposer. Assembly 1504 includes pins 1508, which may include snap-pins 100, push-pins 800, or a combination thereof. Assembly 1504 may further include one or more other features disclosed in one or more examples above.

FIG. 16 depicts effects of bending/warping on electrical connections amongst layers 202.

Pin-based approaches disclosed herein may reduce manufacturing time/costs, relative to screws, since the pins merely need to be pressed in place.

Pin-based approaches disclosed herein may reduce and/or eliminate damage to layers 202 that may otherwise occur due to over-torqued screws.

Pins disclosed herein, and/or other features disclosed herein may be manufactured from non-electrically conductive materials, which may reduce weight, manufacturing costs, and electrical shorts.

Pin-based approaches disclosed herein may be less susceptible to coming loose due to environmental vibration, relative to screws.

Pin-based approaches disclosed herein may be useful to absorb environmental vibration, which may protect circuity within layers 202.

Pin-based approaches disclosed herein and/or other compression features disclosed herein, may be useful to provide more consistent and deterministic compression, relative to screws.

Visual compression features disclosed herein may be useful to readily determine whether suitable compression is applied. Visual compression features disclosed herein may be further useful in high-criticality and/or inhospitable/inaccessible environments (e.g., extra-terrestrial applications). As an example, visual compression features may be remotely monitored (e.g., via optical sensors), such as to permit remote-controlled switchover to a back-up assembly if a loss of compression is detected, before electrical contact is interrupted between adjacent layers of the original assembly.

Additional compression-attached circuit assemblies may be designed and/or constructed based on various combinations of features disclosed herein.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system. ” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An apparatus, comprising:
a pin comprising an elongated body configured to insert into aligned openings of a plurality of circuit boards; and
a locking member configured to retain the pin in a locked position in which the circuit boards are pressed against one another under a compression force.

2. The apparatus of claim 1, wherein the circuit boards comprise:
an interposer circuit board configured to provide electrical connections between electrical contacts of adjacent ones of the circuit boards.

3. The apparatus of claim 1, wherein the circuit boards comprise:
a first circuit board comprising memory;
a second circuit board comprising a processor; and
an interposer circuit board positioned between the first and second circuit boards, configured to provide electrical connections between electrical contacts of the first and second circuit boards.

4. The apparatus of claim 1, wherein the circuit boards comprise:
a first circuit board comprising memory;
a second circuit board comprising a system-on-chip (SoC) that comprises a processor and a memory interface; and
an interposer circuit board positioned between the first and second circuit boards, configured to provide electrical connections between electrical contacts of the first and second circuit boards;
wherein the second circuit board further comprises electrical connections between the SoC and the electrical contacts of the second circuit board.

5. The apparatus of claim 1, wherein the pin comprises a snap-pin.

6. The apparatus of claim 1, wherein the pin comprises a push-pin.

7. The apparatus of claim 1, wherein the pin comprises a spring-loaded pin.

8. The apparatus of claim 1, wherein the pin is removable.

9. The apparatus of claim 1, wherein:
the pin comprises a flange extending outwardly from a first end of the elongated body;
a second end of the elongated body is configured to insert into the aligned openings of the circuit boards;
a diameter of the flange is greater than a diameter of the openings; and
the second end of the elongated body comprises the locking member.

10. The apparatus of claim 9, further comprising a compressible material positioned between one or more of:
a first outermost one of the circuit boards and the flange; and
a second outermost one of the circuit boards and a washer.

11. The apparatus of claim 10, wherein the compressible material comprises one or more of:
an O-ring;
a gasket; and
a film.

12. The apparatus of claim 10, further comprising:
a compression indicator configured to provide a visual indication of a measure of compression of the compressible material.

13. The apparatus of claim 12, wherein the visual indication comprises one or more of:
markings on a surface adjacent to the compressible material; and
a post extending from the surface adjacent to the compressible material.

14. The apparatus of claim 10, wherein the compressible material comprises:
a piezo-chromic electric material that reflects light at a frequency that is based on compression of the piezo-chromic electric material.

15. The apparatus of claim 1, wherein the pin comprises the locking member, the apparatus further comprising:
a counter-sunk washer comprising a base and a counter-sunk portion extending from the base;
wherein an outer diameter of the counter-sunk portion is less than a diameter of the openings of the circuit boards;
wherein the counter-sunk portion has an opening to a chamber therein configured to receive a first end of the elongated body of the pin;
wherein an inner surface of the chamber has a channel configured to receive the locking member.

16. The apparatus of claim 15, wherein the channel comprises a transition surface configured to depress the locking member when the pin is twisted.

17. The apparatus of claim 1, wherein the apparatus is configured as a compression-attached circuit module (CAMM).

18. An apparatus, comprising;
a plurality of circuit boards comprising an interposer circuit board configured to provide electrical connections between electrical contacts of adjacent ones of the circuit boards;
a plurality of pins comprising elongated bodies configured to insert into respective aligned openings of the circuit boards; and
a locking member configured to retain the pins in a locked position in which the circuit boards are pressed against one another under a compression force.

19. The apparatus of claim 18, further comprising:
a compressible material configured to exert a physical force against an outermost one of the circuit boards when the pins are in a locked position.

20. The apparatus of claim 19, further comprising:
a compression indicator configured to provide a visual indication of a measure of compression of the compressible material.
